(19) United States
(12) Patent Application Publication
(10) Pub. No.: US 2023/0006162 A1
(43) Pub. Date: Jan. 5, 2023

(54) LIGHT EMITTING DEVICE, AND METHOD FOR MANUFACTURING LIGHT EMITTING DEVICE

(71) Applicant: SHARP KABUSHIKI KAISHA, Sakai City, Osaka (JP)

(72) Inventors: YUSUKE SAKAKIBARA, Sakai City, Osaka (JP); Masaki YAMAMOTO, Sakai City, Osaka (JP)

(21) Appl. No.: 17/779,719

(22) PCT Filed: Dec. 9, 2019
(86) PCT No.: PCT/JP2019/047978

§ 371 Date: May 25, 2022

(51) Int. Cl. H01L 51/50; H01L 51/56

(52) U.S. Cl. CPC H01L 51/508; H01L 51/5056; H01L 51/56; H01L 2251/303; H01L 2251/5369

(57) ABSTRACT

A light-emitting device includes: a first light-emitting element including a first light-emitting layer configured to emit light having a light-emitting central wavelength of a first wavelength, and a first electron transport layer layered with the first light-emitting layer; and a second light-emitting element including a second light-emitting layer configured to emit light having a light-emitting central wavelength of a second wavelength shorter than the first wavelength, and the second electron transport layer layered with the second light-emitting layer. Each of the first electron transport layer and the second electron transport layer includes a plurality of nanoparticles, and the second electron transport layer includes the plurality of nanoparticles having a smaller average particle size than the plurality of nanoparticles included in the first electron transport layer, and has a smaller thickness than the first electron transport layer.

### TECHNICAL FIELD

An aspect of the disclosure relates to a light-emitting device, and a method for manufacturing the light-emitting device.

### BACKGROUND ART

PTL 1 discloses an organic electroluminescence image display device including an anode, a hole transport layer, a light-emitting layer, an electron transport layer, and a cathode for each light-emitting pixel.

### CITATION LIST

### Patent Literature

PTL 1: JP 2010-244885 A

### SUMMARY OF INVENTION

### Technical Problem

In the organic electroluminescence image display device of PTL 1, light-emitting pixels that emit light of different colors use an electron transport layer made of the same material and having the same thickness. This makes it difficult to improve the transport efficiency of electrons in light-emitting pixels in the organic electroluminescence image display device described in PTL 1, and as a result, it is impossible to improve external quantum efficiency (EQE). In view of the above, an aspect of the disclosure is directed to providing a light-emitting device having, for example, improved external quantum efficiency (EQE), and a method for manufacturing the light-emitting device.

### Solution to Problem

A light-emitting device according to an aspect of the disclosure includes: a first light-emitting element including a first light-emitting layer configured to emit light having a light-emitting central wavelength of a first wavelength, and a first electron transport layer layered with the first light-emitting layer; and a second light-emitting element including a second light-emitting layer configured to emit light having a light-emitting central wavelength of a second wavelength shorter than the first wavelength, and a second electron transport layer layered with the second light-emitting layer, wherein each of the first electron transport layer and the second electron transport layer includes a plurality of nanoparticles, and the second electron transport layer includes the plurality of nanoparticles having a smaller average particle size than the plurality of nanoparticles included in the first electron transport layer, and has a smaller thickness than the first electron transport layer.

A method for manufacturing a light-emitting device according to an aspect of the disclosure includes: forming a first light-emitting layer configured to emit light having a light-emitting central wavelength of a first wavelength: forming a second light-emitting layer configured to emit light having a light-emitting central wavelength of a second wavelength shorter than the first wavelength; forming a first electron transport layer layered with the first light-emitting layer; and forming a second electron transport layer layered with the second light-emitting layer, wherein each of the first electron transport layer and the second electron transport layer includes a plurality of nanoparticles, and the second electron transport layer includes the plurality of nanoparticles having a smaller average particle size than the plurality of nanoparticles included in the first electron transport layer, and has a smaller thickness than the first electron transport layer.

### Advantageous Effects of Invention

According to an aspect of the disclosure, it is possible to provide a light-emitting device having improved external quantum efficiency (EQE) and a method for manufacturing the light-emitting device.

### BRIEF DESCRIPTION OF DRAWINGS

FIG. 1 is a cross-sectional view schematically illustrating a layered structure of a light-emitting device according to an embodiment.

FIG. 2 is a cross-sectional view illustrating a schematic configuration of electron transport layers in the light-emitting device according to the embodiment.

FIG. 3 is an energy diagram illustrating an example of an electron affinity and an ionization potential of quantum dots included in each light-emitting layer of the light-emitting device according to the embodiment.

FIG. 4 is an energy diagram illustrating an example of a Fermi level or an electron affinity, and an ionization potential in each layer in a light-emitting element emitting red light of the light-emitting device according to the embodiment.

FIG. 5 is an energy diagram illustrating an example of a Fermi level or an electron affinity, and an ionization potential in each layer in a light-emitting element emitting green light of the light-emitting device according to the embodiment.

FIG. 6 is an energy diagram illustrating an example of a Fermi level or an electron affinity, and an ionization potential in each layer in a light-emitting element emitting blue light of the light-emitting device according to the embodiment.

FIG. 7 is a diagram illustrating states before and after upper ends of valence band levels and lower ends of conductor levels of the light-emitting layer and the electron transport layer in the light-emitting element emitting blue light of the light-emitting device according to the embodiment are bent.

FIG. 8 is a diagram showing a graph of electron transmittance of the light-emitting device according to the embodiment.

FIG. 9 is a cross-sectional view schematically illustrating a layered structure of a light-emitting device according to a first modified example of the embodiment.

FIG. 10 is a cross-sectional view schematically illustrating a layered structure of a light-emitting device according to a second modified example of the embodiment.

FIG. 11 is a cross-sectional view schematically illustrating a layered structure of a light-emitting device according to a third modified example of the embodiment.

### DESCRIPTION OF EMBODIMENTS

An embodiment according to an aspect of the disclosure will be described below with reference to the drawings.

### EMBODIMENT

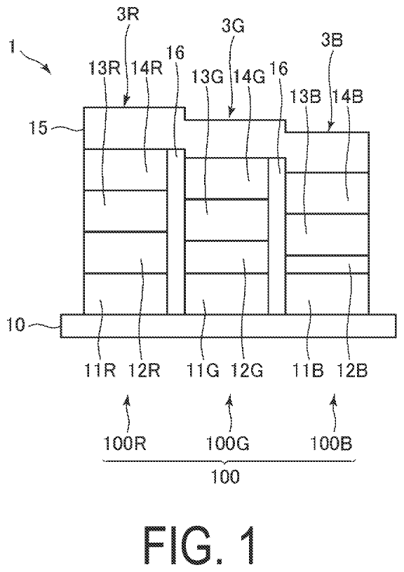

FIG. 1 is a cross-sectional view schematically illustrating a layered structure of a light-emitting device 1 according to an embodiment. The light-emitting device 1 can be used as a display device provided in various electronic devices such as a mobile information terminal or a stationary electronic device, for example. Examples of the mobile information terminal include a portable information device such as a smartphone. Examples of the stationary electronic device include a television receiver. Alternatively, the light-emitting device 1 may be used as various illumination devices, such as a backlight device in a liquid crystal display device or the like, or an illumination device that illuminates various spaces. In the present embodiment, as an example, a case where the light-emitting device 1 is used as a so-called self-emitting display will be mainly described.

The light-emitting device 1 includes a display region of an image provided with a plurality of pixels 100, and a frame region surrounding the display region. Each of the pixels 100 has a plurality of subpixels 100R, 100G, 100B that emit light of different colors.

For example, each of the pixels 100 includes a subpixel 100R that emits red light (light of a first color), a subpixel 100G that emits green light (light of a second color), and a subpixel 100B that emits blue light (light of a first color). Note that the red light refers to light having a light-emitting central wavelength (first wavelength) in a wavelength band of greater than 600 nm and 780 nm or less. Further, the green light refers to light having a light-emitting central wavelength (second wavelength) in a wavelength band of greater than 500 nm and 600 nm or less. The blue light refers to light having a light-emitting central wavelength (third wavelength) in a wavelength band of 400 nm or greater and 500 nm or less.

For example, when a display surface of an image, which is a surface including a display region of an image, is viewed from a direction normal to the display surface of the image (when viewed in a plan view), the subpixel 100R, the subpixel 100G, and the subpixel 100B are adjacent to each other. Note that the arranged order of the subpixel 100R, the subpixel 100G, and the subpixel 100B is not particularly limited.

The light-emitting device 1 includes, for example, an array substrate 10, banks 16, a light-emitting element (first light-emitting element) 3R, a light-emitting element (second light-emitting element) 3G, and a light-emitting element (third light-emitting element) 3B.

The banks 16 are layered on the array substrate 10 so as to divide the subpixels 100R, 100G, 100B. The banks 16 can be formed of, for example, an insulating material such as polyimide or acrylic.

The light-emitting element 3R emits red light and constitutes the subpixel 100R on the array substrate 10. The light-emitting element 3G emits green light and constitutes the subpixel 100G on the array substrate 10. The light-emitting element 3B emits blue light and constitutes the subpixel 100B on the array substrate 10. For example, in a plan view, the light-emitting element 3R, the light-emitting element 3G, and the light-emitting element 3B are adjacent to each other. Note that the arranged order of the light-emitting element 3R, the light-emitting element 3G, and the light-emitting element 3B is not particularly limited.

The array substrate 10 is a substrate provided with a plurality of thin film transistors (TFTs) for controlling light emission and non-light emission of each of the light-emitting elements 3R, 3G, 3B. The array substrate 10 includes, for example, a substrate having flexibility, an inorganic insulating layer layered on the substrate, the plurality of TFTs provided in the inorganic insulating layer, and an interlayer insulating layer (flattening film) covering the plurality of TFTs and layered on the inorganic insulating layer. The substrate having flexibility can be formed of an organic insulating material such as polyimide, for example. The inorganic insulating layer has a single-layer or multilayer structure, and can be formed of, for example, silicon oxide, silicon nitride, or silicon oxynitride. The interlayer insulating layer can be formed of, for example, an organic insulating material such as polyimide or acrylic. In this manner, the array substrate 10 having flexibility can be configured. Note that the array substrate 10 may include a hard substrate containing an inorganic insulating material such as glass, in place of the substrate having flexibility.

For example, the light-emitting element 3R includes a cathode (first cathode) 11R, an electron transport layer (first electron transport layer) 12R, a light-emitting layer (first light-emitting layer) 13R, and a hole transport layer (first hole transport layer) 14R layered in this order from the array substrate 10 side. Further, for example, the light-emitting element 3G includes a cathode (second cathode) 11G, an electron transport layer (second electron transport layer) 12G, a light-emitting layer (second light-emitting layer) 13G, and a hole transport layer (second hole transport layer) 14G layered in this order from the array substrate 10 side. Further, for example, the light-emitting element 3B includes a cathode (third cathode) 11B, an electron transport layer (third electron transport layer) 12B, a light-emitting layer (third light-emitting layer) 13B, and a hole transport layer (third hole transport layer) 14B layered in this order from the array substrate 10 side. In addition, the light-emitting elements 3R, 3G, 3B have an anode 15 layered on the hole transport layers 14R, 14G, 14B.

In the present embodiment, for example, a light emission method of the light-emitting elements 3R, 3G, 3B is an electroluminescence (EL) method in which current flows between the cathodes 11R, 11G, 11B and the anode 15 so that quantum dots included in the light-emitting layers 13R, 13G, 13B emit light.

For example, the cathode 11R, the electron transport layer 12R, the light-emitting layer 13R, and the hole transport layer 14R are provided in an island shape separated for each light-emitting element 3R (in other words, for each subpixel 100R). The cathode 11G, the electron transport layer 12G, the light-emitting layer 13G, and the hole transport layer 14G are provided in an island shape separated for each light-emitting element 3G (in other words, for each subpixel 100G). The cathode 11B, the electron transport layer 12B, the light-emitting layer 13B, and the hole transport layer 14B are provided in an island shape separated for each light-emitting element 3B (in other words, for each subpixel 100G). The anode 15 is not separated for each of the light-emitting elements 3R, 3G, 3B and is provided as a continuous layer over the light-emitting elements 3R, 3G, 3B, for example.

The cathode 11R injects electrons into the electron transport layer 12R. The cathode 11G injects electrons into the electron transport layer 12G. The cathode 11B injects electrons into the electron transport layer 12B. The cathode 11R is provided on a side opposite to the light-emitting layer 13R with respect to the electron transport layer 12R. The cathode 11G is provided on a side opposite to the light-emitting layer 13G with respect to the electron transport layer 12G. The cathode 11B is provided on a side opposite to the light-emitting layer 13B with respect to the electron transport layer 12B.

The cathode 11R, the cathode 11G, and the cathode 11B are separated from each other with the banks 16 interposed therebetween, and are layered on the interlayer insulating layer in the array substrate 10. That is, in a plan view, the cathode 11R, the cathode 11G, and the cathode 11B are adjacent to each other with the banks 16 interposed therebetween. Note that the arranged order of the cathode 11R, the cathode 11G, and the cathode 11B is not particularly limited.

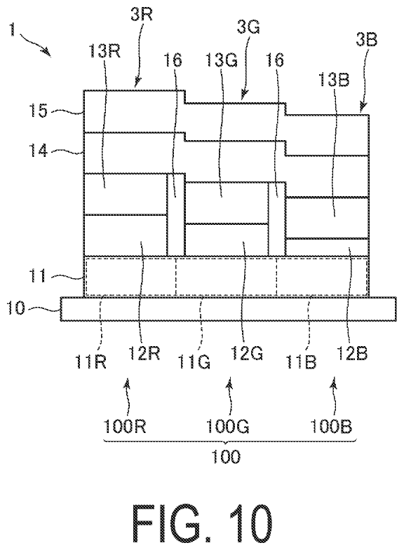

The cathode 11R is connected to a TFT provided in the lower layer of the interlayer insulating layer through a contact hole formed in the interlayer insulating layer. The cathode 11G is connected to a TFT provided in the lower layer of the interlayer insulating layer through a contact hole formed in the interlayer insulating layer. The cathode 11B is connected to a TFT provided in the lower layer of the interlayer insulating layer through a contact hole formed in the interlayer insulating layer. In this manner, the light-emitting device 1 is configured to be able to control light emission and non-light emission for each of the light-emitting elements 3R, 3G, 3B by connecting each of the cathodes 11R, 11G, 11B separated into an island shape to a TFT. This causes the light-emitting device 1 to function as a display device capable of displaying various images. Note that an example of using the light-emitting device 1 as an illumination device will be described below with reference to FIG. 10.

Each of the cathodes 11R, 11G, 11B can be formed by layering, for example, a reflective metal layer having a high reflectivity of visible light and a transparent conductive layer having a high transmittance of visible light in this order. The reflective metal layer having a high reflectivity of visible light can contain metal such as Al, Cu, Au, or Ag, for example. The transparent conductive layer having a high transmittance of visible light can contain a transparent conductive material such as indium tin oxide (ITO), indium zinc oxide (IZO), zinc oxide (ZnO), aluminum-doped zinc oxide (AZO), or gallium-doped zinc oxide (GZO), for example. Layers constituting the cathodes 11R, 11G, 11B can be formed by, for example, sputtering or vapor deposition method. Note that the cathodes 11R, 11G, 11B each are not limited to having a double-layer structure, and may have a multilayer structure with three or more layers layered or may have a single-layer structure.

The banks 16 each cover the contact hole provided in the interlayer insulating layer in the array substrate 10 layered on the interlayer insulating layer in the array substrate 10, for example. The banks 16 can be formed by, for example, applying an organic material such as polyimide or acrylic on the array substrate 10 and then patterning the organic material by photolithography or the like.

The banks 16 cover respective edges of the cathodes 11R, 11G, 11B, for example. As a result, the banks 16 each also function as an edge cover for each of the cathodes 11R, 11G, 11B. That is, the banks 16 can suppress generation of an excessive electric field at edge portions of the cathodes 11R, 11G, 11B.

The electron transport layer 12R transports electrons injected from the cathode 11R to the light-emitting layer 13R. The electron transport layer 12G transports electrons injected from the cathode 11G to the light-emitting layer 13G. The electron transport layer 12B transports electrons injected from the cathode 11B to the light-emitting layer 13B.

The electron transport layer 12R is layered with the light-emitting layer 13R. That is, the electron transport layer 12R is provided between the cathode 11R and the light-emitting layer 13R. The electron transport layer 12G is layered with the light-emitting layer 13G. That is, the electron transport layer 12G is provided between the cathode 11G and the light-emitting layer 13G. The electron transport layer 12B is layered with the light-emitting layer 13B. That is, the electron transport layer 12B is provided between the cathode 11B and the light-emitting layer 13B.

The electron transport layer 12R, the electron transport layer 12G, and the electron transport layer 12B are separated from each other with the banks 16 interposed therebetween. That is, in a plan view, the electron transport layer 12R, the electron transport layer 12G, and the electron transport layer 12B are adjacent to each other with the banks 16 interposed therebetween. Note that the arranged order of the electron transport layer 12R, the electron transport layer 12G, and the electron transport layer 12B is not particularly limited.

The electron transport layers 12R, 12G, 12B each contain a plurality of nanoparticles having electron transportability. The electron transport layers 12R, 12G, 12B each contain nanoparticles including Zn_{1-X}Mg_{X}O (where X satisfies 0≤X<1), for example. For example, the electron transport layer 12G is formed so as to have a smaller particle size of nanoparticles and a smaller thickness than those of the electron transport layer 12R. Further, for example, the electron transport layer 12B is formed so as to have a smaller particle size of nanoparticles and a smaller thickness than those of the electron transport layer 12G. The electron transport layers 12R, 12G, 12B may be formed by separately patterning by an ink-jet method, vapor deposition using a mask, or photolithography, for example.

Note that the electron transport layers 12R, 12G, 12B may each have a function of suppressing transport of positive holes (hole blocking function) from the light-emitting layers 13R, 13G, 13B to the cathodes 11R, 11G, 11B, respectively. Detailed description of the electron transport layers 12R, 12G, 12B will be given below.

The light-emitting layer 13R includes a plurality of quantum dots (semiconductor nanoparticles) that emit red light, thereby emitting red light. The light-emitting layer 13G includes a plurality of quantum dots (semiconductor nanoparticles) that emit green light, thereby emitting green light. The light-emitting layer 13B includes a plurality of quantum dots (semiconductor nanoparticles) that emit blue light, thereby emitting blue light.

For example, the light-emitting layer 13R is provided between the electron transport layer 12R and the hole transport layer 14R. For example, the light-emitting layer 13G is provided between the electron transport layer 12G and the hole transport layer 14G. For example, the light-emitting layer 13B is provided between the electron transport layer 12B and the hole transport layer 14B.

The light-emitting layer 13R, the light-emitting layer 13G, and the light-emitting layer 13B are separated from each other with the banks 16 interposed therebetween. That is, in a plan view, the light-emitting layer 13R, the light-emitting layer 13G, and the light-emitting layer 13B are adjacent to each other with the banks 16 interposed therebetween. Note that the arranged order of the light-emitting layer 13R, the light-emitting layer 13G, and the light-emitting layer 13B is not particularly limited.

The light-emitting layers 13R, 13G, 13B can be formed by separately patterning by an ink-jet method, vapor deposition using a mask, photolithography, or the like. The thickness of each of the light-emitting layers 13R, 13G, 13B can be about 3 nm or greater and 100 nm or less, for example.

Quantum dots included in each of the light-emitting layers 13R, 13G, 13B have a valence band level (equal to an ionization potential) and a conduction band level (equal to an electron affinity), and can be formed of an light emitting material that emits light through recombination of positive holes in the valence band level with electrons in the conduction band level. Light emission from the quantum dots matching in a particle size has a narrower spectrum due to a quantum confinement effect, and thus light emission with a relatively deep color level can be obtained.

The quantum dots included in each of the light-emitting layers 13R, 13G, 13B can contain one or more semiconductor materials selected from the group consisting of CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, and MgTe and combinations thereof, for example. Further, the quantum dots may each be a two-component core type, a three-component core type, a four-component core type, a core-shell type, a core multi-shell type, a doped nanoparticle, or a structure having a composition gradient. In addition, for example, a ligand may be coordinate-bonded to the outer perimeter of a shell. The ligand can be made of an organic matter such as thiol or amine, for example.

The particle size of the quantum dots included in each of the light-emitting layers 13R, 13G, 13B can be about from 3 nm to 15 nm, for example. The emission wavelength of the quantum dots included in each of the light-emitting layers 13R, 13G, 13B can be controlled by the particle size of the quantum dots. Thus, it is possible to obtain light emission of each color (for example, red, green, and blue) by controlling the particle size of the quantum dots included in each of the light-emitting layers 13R, 13G, 13B.

In the present embodiment, as an example, the quantum dots included in the light-emitting layer 13R, the quantum dots included in the light-emitting layer 13G, and the quantum dots included in the light-emitting layer 13B each contain a material of the same composition system, and have different particle sizes. For example, the particle size of the quantum dots included in the light-emitting layer 13R is larger than the particle size of the quantum dots included in the light-emitting layer 13G. In addition, the particle size of the quantum dots included in the light-emitting layer 13G is larger than the particle size of the quantum dots included in the light-emitting layer 13B.

Note that, for example, the particle size of the quantum dots included in the light-emitting layer 13R refers to an average of particle sizes of a plurality of arbitrary quantum dots included in the light-emitting layer 13R, the particle size of the quantum dots included in the light-emitting layer 13G refers to an average of particle sizes of a plurality of arbitrary quantum dots included in the light-emitting layer 13G, and the particle size of the quantum dots included in the light-emitting layer 13B refers to an average of particle sizes of a plurality of arbitrary quantum dots included in the light-emitting layer 13B.

The quantum dots included in the light-emitting layer 13R, the quantum dots included in the light-emitting layer 13G, and the quantum dots included in the light-emitting layer 13B may each contain materials of different types of composition systems.

The hole transport layer 14R transports positive holes injected from the anode 15 to the light-emitting layer 13R. The hole transport layer 14G transports positive holes injected from the anode 15 to the light-emitting layer 13G. The hole transport layer 14B transports positive holes injected from the anode 15 to the light-emitting layer 13B.

The hole transport layer 14R is provided on a side opposite to the electron transport layer 12R with respect to the light-emitting layer 13R. That is, the hole transport layer 14R is provided between the anode 15 and the light-emitting layer 13R. The hole transport layer 14G is provided on a side opposite to the electron transport layer 12G with respect to the light-emitting layer 13G. That is, the hole transport layer 14G is provided between the anode 15 and the light-emitting layer 13G. The hole transport layer 14B is provided on a side opposite to the electron transport layer 12B with respect to the light-emitting layer 13B. That is, the hole transport layer 14B is provided between the anode 15 and the light-emitting layer 13R.

The hole transport layer 14R, the hole transport layer 14G, and the hole transport layer 14B are separated from each other with the banks 16 interposed therebetween. That is, in a plan view, the hole transport layer 14R, the hole transport layer 14G, and the hole transport layer 14B are adjacent to each other with the banks 16 interposed therebetween. Note that the arranged order of the hole transport layer 14R, the hole transport layer 14G, and the hole transport layer 14B is not particularly limited.

The hole transport layers 14R, 14G, 14B each contain a hole transport material. The hole transport layers 14R, 14G, 14B may each include, for example, polyethylene dioxythiophene/polystyrene sulphonate (PEDOT:PSS), poly-N-vinyl carbazole (PVK), poly[(9,9-dioctylfluorenyl-2,7-diyl)-co-(4,4′-(N-(4-sec-butylphenyl)diphenylamine)](TFB), or N,N′-bis(4-butylphenyl)-N,N′-bis(phenyl)-benzidine) (poly-TPD), or may include a plurality of these materials. The hole transport layers 14R, 14G, 14B can each be formed by separately patterning by an ink-jet method, vapor deposition using a mask, photolithography, or the like. The thickness of each of the hole transport layers 14R, 14G, 14B can be about 1 nm or greater and 100 nm or less, for example. The hole transport layers 14R, 14G, 14B may contain different types of hole transport materials. In the present embodiment, as an example, the hole transport layers 14R, 14G, 14B contain the same type of a hole transport material.

The anode 15 injects positive holes into each of the hole transport layers 14R, 14G, 14B. The anode 15 is provided on a side opposite to the electron transport layers 12R, 12G, 12B with respect to the light-emitting layers 13R, 13G, 13B. That is, the anode 15 is layered on the hole transport layers 14R, 14G, 14B and the banks 16. For example, the anode 15 is a common electrode continuous over the light-emitting elements 3R, 3G, 3B. For example, the anode 15 is a layer continuous over the entire surface of the display region in the light-emitting device 1, that is formed in a solid shape.

For example, the anode 15 can be made of a transparent conductive layer having a high transmittance of visible light. The transparent conductive layer having a high transmittance of visible light can be formed by using, for example, ITO, IZO, ZnO, AZO, or GZO. The anode 15 can be formed by, for example, a sputtering or vapor deposition method.

Further, a sealing layer (not illustrated) is provided on the anode 15. The sealing layer includes, for example, a first inorganic sealing layer covering the anode 15, an organic buffer layer that is a layer above the first inorganic sealing layer (a layer on a side opposite to the anode 15 side), and a second inorganic sealing layer that is a layer above the organic buffer layer (a layer on a side opposite to the first inorganic layer side). The sealing layer prevents penetration of foreign matters such as water and oxygen into the light-emitting device 1.

The first inorganic sealing layer and the second inorganic sealing layer may each have a single-layer structure using an inorganic insulating material such as a silicon oxide layer, a silicon nitride layer, or a silicon oxynitride layer, or may have a multilayer structure in which these layers are combined. The layers of each of the first inorganic sealing layer and the second inorganic sealing layer can be formed by, for example, a CVD method.

The organic buffer layer has a flattening effect, and is, for example, a translucent resin layer that transmits visible light. The organic buffer layer can be formed of a coatable organic material such as acrylic. Further, a function film (not illustrated) may be provided on the sealing layers. The function film has, for example, at least one of an optical compensation function, a touch sensor function, and a protection function.

Positive holes injected from the anode 15 to the hole transport layers 14R, 14G, 14B are further transported from the hole transport layer 14R to the light-emitting layer 13R, transported from the hole transport layer 14G to the light-emitting layer 13G, and transported from the hole transport layer 14B to the light-emitting layer 13B. Further, electrons injected from the cathode 11R to the electron transport layer 12R are further transported from the electron transport layer 12R to the light-emitting layer 13R. Further, electrons injected from the cathode 11G to the electron transport layer 12G are further transported from the electron transport layer 12G to the light-emitting layer 13G. Further, electrons injected from the cathode 11B to the electron transport layer 12B are further transported from the electron transport layer 12B to the light-emitting layer 13B.

Then, the positive holes and the electrons transported to the light-emitting layers 13R, 13G, 13B recombine in the quantum dots to generate excitons. Then, the excitons return from an excited state to a ground state, so that the quantum dots emit light. That is, the quantum dots in the light-emitting layer 13R emit red light, the quantum dots in the light-emitting layer 13G emit green light, and the quantum dots in the light-emitting layer 13B emit blue light.

Note that the light-emitting device 1 according to the present embodiment has been described taking, as an example, a top-emitting type in which light emitted by the light-emitting layers 13R, 13G, 13B is caused to pass through the hole transport layers 14R, 14G, 14B, and the anode 15, thereby being taken to a side opposite to the array substrate 10 (a upper side of the light-emitting layers 13R, 13G, 13B in FIG. 1). However, the light-emitting device 1 may be of a bottom emission type in which light emitted by the light-emitting layers 13R, 13G, 13B is caused to pass through the electron transport layers 12R, 12G, 12B, the cathodes 11R, 11G, 11B, and the array substrate 10, thereby being taken to the array substrate 10 side (a lower side of the light-emitting layers 13R, 13G, 13B in FIG. 1). In this case, it is required that the anode 15 contains a reflective metal layer having a high reflectivity of visible light, and that the cathodes 11R, 11G, 11B are formed by using a transparent conductive layer having a high transmittance of visible light.

Note that the layered structure of each of the light-emitting elements 3R, 3G, 3B is not limited to the structure illustrated in FIG. 1, and for example, each of the light-emitting elements 3R, 3G, 3B may further have another functional layer. For example, the light-emitting element 3R may include a hole injection layer that increases an injection efficiency of positive holes from the anode 15 to the hole transport layer 14R, between the anode 15 and the hole transport layer 14R. Further, for example, the light-emitting element 3G may include a hole injection layer that increases an injection efficiency of positive holes from the anode 15 to the hole transport layer 14G, between the anode 15 and the hole transport layer 14G. For example, the light-emitting element 3B may include a hole injection layer that increases an injection efficiency of positive holes from the anode 15 to the hole transport layer 14B, between the anode 15 and the hole transport layer 14B. In a case where a hole injection layer is provided in each of the light-emitting elements 3R, 3G, 3B, the hole injection layers may be provided in an island shape separated for each of the light-emitting elements 3R, 3G, 3B, or may be provided as a continuous layer connected to each other.

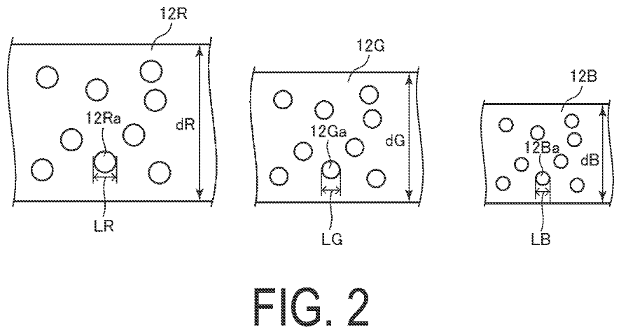

FIG. 2 is a cross-sectional view illustrating a schematic configuration of the electron transport layers 12R, 12G, 12B in the light-emitting device 1 according to the embodiment.

The electron transport layer 12R includes a plurality of nanoparticles 12Ra having electron transportability. The electron transport layer 12G includes a plurality of nanoparticles 12Ga having electron transportability. The electron transport layer 12B includes a plurality of nanoparticles 12Ba having electron transportability. For example, the nanoparticles 12Ra, 12Ga, 12Ba can each contain TiO₂, Al-added ZnO (ZAO), Zn_{1-X}Mg_{X}O (where 0≤X<1 is satisfied, including ZnO at X=0), ITO, or InGaZnO_{X}, or the like. In the present embodiment, for example, the nanoparticles 12Ra, 12Ga, 12Ba each contain Zn_{1-X}Mg_{X}O (where 0≤X<1 is satisfied).

Note that the nanoparticles 12Ra, 12Ga, 12Ba may be composed of different materials, but are preferably composed of the same material. In addition, materials composing the nanoparticles 12Ra, 12Ga, 12Ba may have different compositions, but preferably have the same composition. This makes it possible to more reliably obtain the light-emitting device 1 with improved external quantum efficiency (EQE). For example, in a case where the nanoparticles 12Ra, 12Ga, 12Ba each contain Zn_{1-X}Mg_{X}O (where 0≤X<1 is satisfied) as a material, X in Zn_{1-X}Mg_{X}O is preferably the same (that is, the same composition).

The thickness of each of the electron transport layers 12R, 12G, 12B can be, for example, about 3 nm or greater and 100 nm or less.

The particle size of the nanoparticles 12Ra is defined as a particle size LR, and the particle size of the nanoparticles 12Ga is defined as a particle size LG, and the particle size of the nanoparticles 12Ba is defined as a particle size LB. In the light-emitting device 1, the particle size LG is smaller than the particle size LR, and the particle size LB is smaller than the particle size LG. Further, the thickness of the electron transport layer 12R is defined as a thickness dR, the thickness of the electron transport layer 12G is defined as a thickness dG, and the thickness of the electron transport layer 12B is defined as a thickness dB. In the light-emitting device 1, the electron transport layer 12G is formed so as to have the thickness dG smaller than the thickness dR of the electron transport layer 12R. In addition, the electron transport layer 12R is formed so as to have the thickness dR smaller than the thickness dG of the electron transport layer 12G. Note that details of the particle sizes LR, LG, LB, and the thicknesses dR, dG, dB are made efficient.

Note that the particle size LR is an average of particle sizes of a plurality of arbitrary nanoparticles 12Ra included in the electron transport layer 12R, for example. Further, the particle size LG is an average of particle sizes of a plurality of arbitrary nanoparticles 12Ga included in the electron transport layer 12G, for example. Further, the particle size LB is an average of particle sizes of a plurality of arbitrary nanoparticles 12Ba included in the electron transport layer 12B, for example. However, the particle sizes LR, LG, LB of the nanoparticles 12Ra, 12Ga, 12Ba may be represented using an index other than the average.

In addition, the “particle size” of each of the nanoparticles 12Ra, 12Ga, 12Ba is a particle size on the assumption that each of the nanoparticles 12Ra, 12Ga, 12Ba is a true sphere. However, in fact, nanoparticles 12Ra, 12Ga, 12Ba that are not considered to be true spheres are present. However, even in a case where the nanoparticles 12Ra, 12Ga, 12Ba have some distortions from the true sphere, the nanoparticles 12Ra, 12Ga, 12Ba can perform substantially the same function as with the true sphere. Thus, the “particle size” of each of the nanoparticles 12Ra, 12Ga, 12Ba is assumed to refer to the particle size of the true sphere having the same volume as each of the nanoparticles 12Ra, 12Ga, 12Ba.

Further, in the present embodiment, for example, the thickness dR is defined as an average of thicknesses of the electron transport layer 12R at predetermined positions in a plan view of a plurality of arbitrary subpixels 100R included in the light-emitting device 1 (for example, centers of the subpixels 100R). Further, for example, the thickness dG is defined as an average of thicknesses of the electron transport layer 12G at predetermined positions in a plan view of a plurality of arbitrary subpixels 100G included in the light-emitting device 1 (for example, centers of the subpixels 100G). Further, for example, the thickness dB is defined as an average of thicknesses of the electron transport layer 12B at predetermined positions in a plan view of a plurality of arbitrary subpixels 100B included in the light-emitting device 1 (for example, centers of the subpixels 100B).

However, the thicknesses dR, dG, dB each are not limited to the average, and may be represented using an index other than the average. For example, the thickness dR may be a thickness of the electron transport layer 12R at a predetermined position in a plan view of any one of a plurality of subpixels 100R included in the light-emitting device 1 (for example, the center of the subpixel 100R). Further, for example, the thickness dG may be a thickness of the electron transport layer 12G at a predetermined position in a plan view of any one of a plurality of subpixels 100G included in the light-emitting device 1 (for example, the center of the subpixel 100G). Further, for example, the thickness dB may be a thickness of the electron transport layer 12B at a predetermined position in a plan view of any one of a plurality of subpixels 100B included in the light-emitting device 1 (for example, the center of the subpixel 100B).

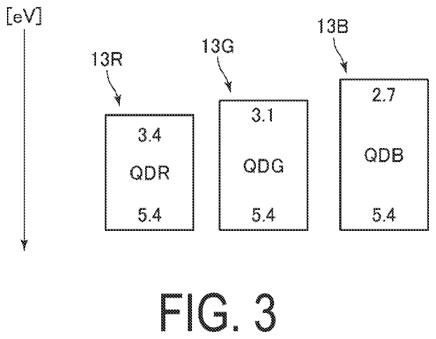

FIG. 3 is an energy diagram illustrating an example of an electron affinity and an ionization potential of quantum dots included in each of the light-emitting layers 13R, 13G, 13B of the light-emitting device 1 according to the embodiment. FIG. 3 illustrates, from left to right, an example of each of the electron affinity and the ionization potential of the quantum dots included in the light-emitting layer 13R (indicated as QDR), the electron affinity and the ionization potential of the quantum dots included in the light-emitting layer 13G (indicated as QDG), and the electron affinity and the ionization potential of the quantum dots included in the light-emitting layer 13B (indicated as QDB in FIG. 3).

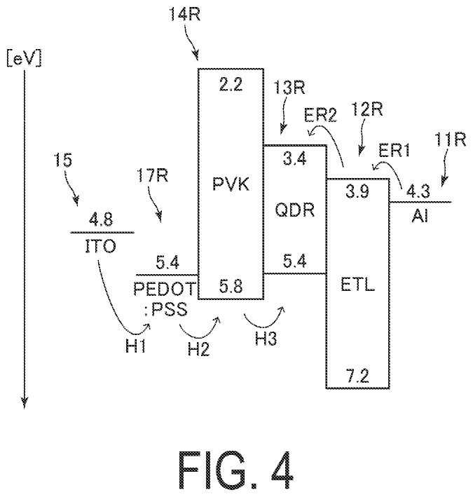

FIG. 4 is an energy diagram illustrating an example of a Fermi level or an electron affinity, and an ionization potential in each layer of the light-emitting element 3R of the light-emitting device 1 according to the embodiment.

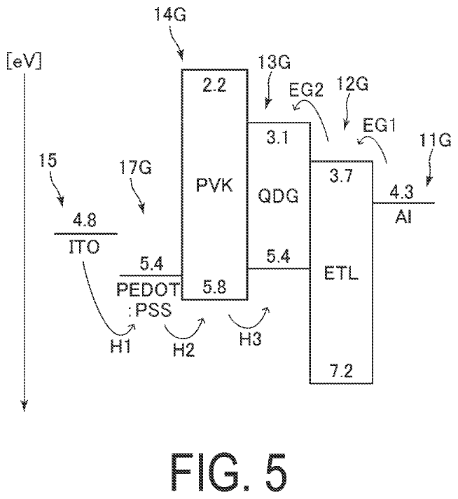

FIG. 5 is an energy diagram illustrating an example of a Fermi level or an electron affinity, and an ionization potential in each layer of the light-emitting element 3G of the light-emitting device 1 according to the embodiment.

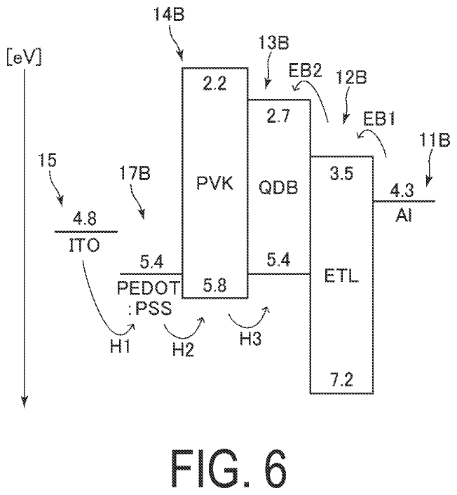

FIG. 6 is an energy diagram illustrating an example of a Fermi level or an electron affinity, and an ionization potential in each layer of the light-emitting element 3B of the light-emitting device 1 according to the embodiment.

Note that FIG. 4 illustrates an energy diagram in a case where a hole injection layer 17R is provided between the anode 15 and the hole transport layer 14R in the light-emitting element 3R. Further, FIG. 5 illustrates an energy diagram in a case where a hole injection layer 17G is provided between the anode 15 and the hole transport layer 14G in the light-emitting element 3G. Further, FIG. 6 illustrates an energy diagram in a case where a hole injection layer 17B is provided between the anode 15 and the hole transport layer 14B in the light-emitting element 3B.

Note that for the electron affinities and the ionization potentials of the quantum dots included in the light-emitting layers 13R, 13G, 13B in FIGS. 3 to 6, electron affinities and ionization potentials of cores in which quantum dots are formed of a material of the same composition system are illustrated as an example. For example, in a case where quantum dots included in each of the light-emitting layers 13R, 13G, 13B have a core/shell structure, in FIGS. 3 to 6, of cores and shells of quantum dots included in each of the light-emitting layers 13R, 13G, 13B, an example of electron affinities and ionization potentials of cores is illustrated. Note that in the following description, the electron affinity and the ionization potential in quantum dots of each of the light-emitting layers 13R, 13G, 13B will be sometimes simply referred to as the electron affinity and the ionization potential of each of the light-emitting layers 13R, 13G, 13B.

FIG. 4 illustrates, from left to right, an example of each of the Fermi level of the anode 15 (indicated as ITO), the Fermi level of the hole injection layer 17R (indicated as PEDOT:PSS), the electron affinity and the ionization potential of the hole transport layer 14R (indicated as PVK), the electron affinity and the ionization potential of quantum dots of the light-emitting layer 13R (indicated as QDR), the electron affinity and the ionization potential of the electron transport layer 12R (indicated as ETL), and the Fermi level of the cathode 11R (indicated as Al).

FIG. 5 illustrates, from left to right, an example of each of the Fermi level of the anode 15 (indicated as ITO), the Fermi level of the hole injection layer 17G (indicated as PEDOT:PSS), the electron affinity and the ionization potential of the hole transport layer 14G (indicated as PVK), the electron affinity and the ionization potential of quantum dots of the light-emitting layer 13G (indicated as QDG), the electron affinity and the ionization potential of the electron transport layer 12G (indicated as ETL), and the Fermi level of the cathode 11G (indicated as Al).

FIG. 6 illustrates, from left to right, an example of each of the Fermi level of the anode 15 (indicated as ITO), the Fermi level of the hole injection layer 17B (indicated as PEDOT:PSS), the electron affinity and the ionization potential of the hole transport layer 14B (indicated as PVK), the electron affinity and the ionization potential of quantum dots of the light-emitting layer 13B (indicated as QDB), the electron affinity and the ionization potential of the electron transport layer 12B (indicated as ETL), and the Fermi level of the cathode 11B (indicated as Al).

FIGS. 3 to 6 indicate an example of the Fermi level of each of the anode 15 and the cathodes 11R, 11G, 11B in units of eV Further, an example of the Fermi level of each of the hole injection layers 17R, 17G, 17B is indicated in units of eV. Further, in each of the hole transport layers 14R, 14G, 14B, the quantum dots of each of the light-emitting layers 13R, 13G, 13B, and the electron transport layers 12R, 12G, 12B, an example of the ionization potential of each layer based on the vacuum level is indicated below in eV, and an example of the electron affinity of each layer based on the vacuum level is indicated above in units of eV.

In the following description, both the ionization potential and the electron affinity are assumed to be based on the vacuum level when the ionization potential or the electron affinity is described simply.

In the description using the energy diagrams illustrated in FIGS. 3 to 6, as an example, it is assumed that the anode 15 includes ITO, the hole injection layers 17R, 17G, 17B each include PEDOT:PSS, the hole transport layers 14R, 14G, 14B each include PVK, and the cathodes 11R, 11G, 11B each include Al. Further, the cores of the quantum dots of the light-emitting layers 13R, 13G, 13B are assumed to include a material of the same composition system. As an example, the cores of the quantum dots of the light-emitting layers 13R, 13G, 13B are assumed to include CdSe.

Here, as an example, the nanoparticles 12Ra, 12Ga, 12Ba of the electron transport layers 12R, 12G, 12B are each assumed to include ZnO (that is, Zn_{1-X}Mg_{X}O in a case of X=0). Further, as an example here, it is assumed that the particle size LR of the nanoparticles 12Ra is 6 nm, the particle size LG of the nanoparticles 12Ga is 3 nm, the particle size LB of the nanoparticles 12Ba is 2 nm, the thickness dR of the electron transport layer 12R is 60 nm, the thickness dG of the electron transport layer 12G is 30 nm, and the thickness dB of the electron transport layer 12B is 20 nm.

Here, according to measurement by the present inventors, it has been found that in a case where the quantum dots of the light-emitting layers 13R, 13G, 13B include cores containing the same composition system, the valence band levels (equal to ionization potentials) of the cores are considered to be substantially the same regardless of a wavelength of light emitted by each quantum dot.

The inventors measured ionization potentials of the quantum dots of the light-emitting layers 13R, 13G, 13B as follows. Quantum dots were dispersed in an organic solvent such as hexane or toluene to prepare a dispersion solution. Next, the prepared dispersion solution was applied onto an indium tin oxide (ITO) layer of a glass substrate having the ITO layer (thickness of 70 nm) on the main surface thereof, and the organic solvent was evaporated to form a light-emitting layer having a thickness of 30 nm, thereby producing a sample for measuring the ionization potential.

For the produced sample, a photoelectron spectrometer in air (“AC-3” available from RIKEN KEIKI Co., Ltd.) was used to perform photoelectron spectroscopy, thereby measuring the ionization potential.

Specifically, a quantity of incident light was fixed to a quantity of light with which a peak derived from an ITO layer to be observed at around 4.8 eV was not substantially observed, and a quantum yield was measured while changing an electron volt (eV) to measure a relationship between the electron volt and the quantum yield. As a result, an electron volt at which the quantum yield was increased when the electron volt was increased was determined to be the ionization potential.

From a finished product as well, it is possible to measure the ionization potential assuming that ionization potentials of quantum dots having substantially the same composition and the same particle size (the tolerance is within +2 nm) are equal to each other. Note that “ionization potentials are equal to each other” means that the tolerance is within ±0.1 eV.

That is, first, a display is cut by laser cutting or the like to expose a cross section of a light-emitting layer. The exposed cross section is observed using a SEM-EDX to identify the composition and the particle size of the quantum dots. Specifically, the composition of the quantum dots is CdSe. The particle size of the quantum dots is calculated by arbitrarily selecting about 100 quantum dots of the quantum dot layer having a thickness of about 30 nm included in a field of view of a size of about 2 μm or greater and 3 μm or less, measuring areas of the selected quantum dots, and determining an average of diameters of circles having the areas. The particle size of the quantum dots is 5 nm.

Then, quantum dots having the above-identified composition and particle size are produced, so that the ionization potential can be measured by a method similar to the method described above.

The ionization potentials of the quantum dots of the light-emitting layers 13R, 13G, 13B are equal to each other, and are 5.4 eV. Note that “ionization potentials are equal to each other” means that the tolerance is within ±0.1 eV.

On the other hand, the conduction band levels (equivalent to electron affinities) of the quantum dots of the light-emitting layers 13R, 13G, 13B change depending on the wavelength of light emitted from each quantum dot even when the quantum dots include a material of the same composition system. In particular, the conduction band level of the quantum dots of each of the light-emitting layers 13R, 13G, 13B has a deeper energy level as a wavelength of light emitted from the quantum dots is longer, and has a shallower energy level as a wavelength of light emitted from the quantum dots is shorter.

For example, as illustrated in FIG. 3, in the present embodiment, the electron affinity of the quantum dots of the light-emitting layer 13R is 3.4 eV, the electron affinity of the quantum dots of the light-emitting layer 13G is 3.1 eV, and the electron affinity of the quantum dots of the light-emitting layer 13B is 2.7 eV. In this way, the electron affinity of the quantum dots in the light-emitting layer 13B is smaller than the electron affinity of the quantum dots in the light-emitting layer 13G. Further, the electron affinity of the quantum dots in the light-emitting layer 13G is smaller than the electron affinity of the quantum dots in the light-emitting layer 13R.

In addition, as illustrated in FIGS. 4 to 6, for example, the Fermi level of the anode 15 common to the light-emitting elements 3R, 3G, 3B is 4.8 eV. Further, for example, the Fermi level of each of the hole injection layers 17R, 17G, 17B is 5.4 eV.

In addition, for example, the ionization potential of each of the hole transport layers 14R, 14G, 14B is 5.8 eV, and the electron affinity thereof is 2.2 eV. As described above, the ionization potentials of the hole transport layers 14R, 14G, 14B are equal to each other, and the electron affinities thereof are equal to each other. Note that “ionization potentials are equal to each other” means that the tolerance is within ±0.1 eV. Further, “electron affinities are equal to each other” means that the tolerance is within ±0.1 eV.

For example, the ionization potential of each of the electron transport layers 12R, 12G, 12B is 7.2 eV, and the ionization potentials thereof are equal to each other. Note that “ionization potentials are equal to each other” means that the tolerance is within f0.1 eV.

In addition, as illustrated in FIG. 4, for example, the electron affinity of the electron transport layer 12R is 3.9 eV. Further, as illustrated in FIG. 5, for example, the electron affinity of the electron transport layer 12G is 3.7 eV. As illustrated in FIG. 6, for example, the electron affinity of the electron transport layer 12B is 3.5 eV As described above, in the present embodiment, the electron affinity of the electron transport layer 12B is the electron affinity or less of the electron transport layer 12G. Further, the electron affinity of the electron transport layer 12G is the electron affinity or less of the electron transport layer 12R.

Next, with reference to FIGS. 4 to 6, a state in which positive holes and electrons are transported in each layer of the light-emitting elements 3R, 3G, 3B will be described. In the light-emitting device 1, current is flowed between the anode 15 and the cathodes 11R, 11G, 11B.

Then, as indicated by an arrow H1 in FIG. 4, positive holes are injected from the anode 15 into the hole injection layer 17R. As indicated by an arrow H1 in FIG. 5, positive holes are injected from the anode 15 into the hole injection layer 17G. As indicated by an arrow H1 in FIG. 6, positive holes are injected from the anode 15 to the hole injection layer 17B.

Here, for example, a barrier in injecting or transporting positive holes from a first layer to a second layer different from the first layer is represented by an energy obtained by subtracting the ionization potential of the first layer from the ionization potential of the second layer. Thus, a barrier in injecting positive holes indicated by the arrow H1 (FIGS. 4 to 6) is 0.6 eV regardless of types of the light-emitting elements 3R, 3G, 3B.

Further, as indicated by an arrow ER1 in FIG. 4, electrons are injected from the cathode 11R into the electron transport layer 12R. As indicated by an arrow ER1 in FIG. 5, electrons are injected from the cathode 11G into the electron transport layer 12G. As indicated by an arrow ER1 in FIG. 6, electrons are injected from the cathode 11B into the electron transport layer 12B.

Here, for example, a barrier in injecting or transporting electrons from a first layer to a second layer different from the first layer is represented by an energy obtained by subtracting the electron affinity of the second layer from the electron affinity of the first layer. Thus, a barrier in injecting electrons indicated by the arrow ER1 (FIG. 4) is 0.4 eV. Further, a barrier in injecting electrons indicated by an arrow EG1 (FIG. 5) is 0.6 eV. Further, for this reason, a barrier in injecting electrons indicated by an arrow EB1 (FIG. 6) is 0.8 eV.

As indicated by an arrow H2 in each of FIGS. 4 to 6, a barrier in injecting positive holes from the hole injection layer 17R into the hole transport layer 14R is 0.4 eV, a barrier in injecting positive holes from the hole injection layer 17G into the hole transport layer 14G is 0.4 eV, and a barrier in injecting positive holes from the hole injection layer 17B into the hole transport layer 14B is 0.4 eV. Further, as indicated by an arrow H3 in each of FIGS. 4 to 6, a barrier in transporting positive holes from each of the hole transport layers 14R, 14G, 14B to each of the light-emitting layers 13R, 13G, 13B is 0.4 eV.

As indicated by an arrow ER2 in FIG. 4, a barrier in transporting electrons from the electron transport layer 12R to the light-emitting layer 13R is 0.5 eV. Further, as indicated by an arrow EG2 in FIG. 5, a barrier in transporting electrons from the electron transport layer 12G to the light-emitting layer 13G is 0.6 eV. Further, as illustrated in an arrow EB2 in FIG. 6, a barrier in transporting electrons from the electron transport layer 12B to the light-emitting layer 13B is 0.8 eV.

In this way, based on the recombination of the positive holes and the electrons transported to the light-emitting layers 13R, 13G, 13B in the quantum dots in the light-emitting layers 13R, 13G, 13B, the quantum dots in the light-emitting layer 13R emit light, the quantum dots in the light-emitting layer 13G emit light, and the quantum dots in the light-emitting layer 13B emit light.

Here, as described above, the electron affinity of the light-emitting layer 13G (for example, 3.1 eV (see FIG. 5)) is smaller than the electron affinity of the light-emitting layer 13R (for example, 3.4 eV (see FIG. 4)). In addition, the electron affinity of the light-emitting layer 13B (for example, 2.7 eV (see FIG. 5)) is small than the electron affinity of the light-emitting layer 13G (for example, 3.1 eV (see FIG. 5)). That is, the electron affinity becomes smaller in the order of the light-emitting layer 13R, the light-emitting layer 13G, and the light-emitting layer 13B. In other words, the ionization potentials of the light-emitting layer 13R, the light-emitting layer 13G, and the light-emitting layer 13B are equal (for example, 5.4 eV (FIGS. 4 to 6)), and in the order of the light-emitting layer 13R, the light-emitting layer 13G, and the light-emitting layer 13B, a band gap represented by the difference between the ionization potential and the electron affinity becomes wider.

For example, in the organic electroluminescence image display device of PTL 1, electron affinities of light-emitting layers among light-emitting pixels that emit light of different colors are different. However, in the organic electroluminescence image display device, electron transport layers having the same material and the same thickness are used among the light-emitting pixels that emit light of different colors, and thus electron affinities of the electron transport layers are the same among the light-emitting pixels that emit light of different colors.

Thus, for example, it is assumed that in a light-emitting pixel that emits red light, in order to suppress both an injection barrier of electrons from the cathode to the electron transport layer and a transport barrier of electrons from the electron transport layer to the light-emitting layer, the material and the thickness of the electron transport layer are adjusted in such a manner that the electron affinity of the electron transport layer is intermediate between the electron affinity of a red light-emitting layer and the Fermi level of the cathode. As a result, for example, in a light-emitting pixel that emits green light, inversely, a difference from the intermediate value between the electron affinity of a green light-emitting layer and the Fermi level of the cathode is increased. Furthermore, also in a light-emitting pixel that emits blue light, a difference from the intermediate value between the electron affinity of the blue light-emitting layer and the Fermi level of the cathode is increased.

In this way, in the organic electroluminescence image display device of PTL 1, it is not possible to increase a transport efficiency of electrons as the entire light-emitting pixels, including a light-emitting pixel that emits red light, a light-emitting pixel that emits green light, and a light-emitting pixel that emits blue light. That is, according to the organic electroluminescence image display device, the external quantum efficiency (EQE) cannot be improved.

On the other hand, according to the light-emitting device 1 of the present embodiment, the electron transport layer 12R layered with the light-emitting layer 13R contains the nanoparticles 12Ra, the electron transport layer 12G layered with the light-emitting layer 13G contains the nanoparticles 12Ga, and the electron transport layer 12B layered with the light-emitting layer 13B contains the nanoparticles 12Ba.

The particle size LG of the nanoparticles Ga contained in the electron transport layer 12G is smaller than the particle size LR of the nanoparticles Ra contained in the electron transport layer 12R. Furthermore, the particle size LB of the nanoparticles Ba contained in the electron transport layer 12B is smaller than the particle size LG of the nanoparticles Ga contained in the electron transport layer 12G.

Thus, the electron affinity can be reduced in the order of the electron transport layer 12R, the electron transport layer 12G, and the electron transport layer 12B. In other words, the ionization potentials of the electron transport layer 12R, the electron transport layer 12G, and the electron transport layer 12B are equal (for example, 7.2 eV (FIGS. 4 to 6)), and thus the band gap can be widened in the arranged order of the electron transport layer 12R, the electron transport layer 12G, and the electron transport layer 12B. Further in other words, the order in which the electron affinity is reduced in the order of the electron transport layer 12R, the electron transport layer 12G, and the electron transport layer 12B can be adjusted to the order in which the electron affinities of the light-emitting layer 13R, the light-emitting layer 13G, and the light-emitting layer 13B to which the electron transport layer 12R, the electron transport layer 12B, and the electron transport layer 12G transport electrons are reduced.

That is, according to the light-emitting device 1, as compared to the organic electroluminescence image display device of PTL 1, in all the light-emitting elements including the light-emitting element 3R, the light-emitting element 3G, and the light-emitting element 3B, the electron affinity of the electron transport layer can be brought close to the intermediate value of the electron affinity of the light-emitting layer and the Fermi level of the cathode.

Specifically, for example, the electron affinity of the electron transport layer 12R can be brought closer to the intermediate value between the electron affinity of the light-emitting layer 13R and the Fermi level of the cathode 11R. Further, the electron affinity of the electron transport layer 12G can be brought closer to the intermediate value between the electron affinity of the light-emitting layer 13G and the Fermi level of the cathode 11G. In addition, the electron affinity of the electron transport layer 12B can be brought closer to the intermediate value between the electron affinity of the light-emitting layer 13B and the Fermi level of the cathode 11B.

Thus, according to the light-emitting device 1, as compared to the organic electroluminescence image display device of PTL 1, it is possible to reduce the barrier when electrons are transported from the cathode 11R to the light-emitting layer 13R through the electron transport layer 12R, the barrier when electrons are transported from the cathode 11G to the light-emitting layer 13G through the electron transport layer 12G, and the barrier when electrons are transported from the cathode 11B to the light-emitting layer 13B through the electron transport layer 12B.

For this reason, as compared to the organic electroluminescence image display device of PTL 1, according to the light-emitting device 1, it is possible to improve the transport efficiency of electrons as a whole of the light-emitting element 3R, the light-emitting element 3G, and the light-emitting element 3B. That is, it is possible to improve the external quantum efficiency (EQE) of the light-emitting device 1.

Here, when the particle size of nanoparticles in an electron transport layer decreases, a proportion of the surface area per unit volume of the nanoparticles increases. In other words, a contact resistance per unit volume of nanoparticles (contact resistance between surfaces of the nanoparticles and a region around the nanoparticles) is increased. As a result, it is considerable that an electrical resistance of the entire electron transport layer tends to increase, the amount of electrons injected from a cathode into a light-emitting layer through the electron transport layer is reduced, and the external quantum efficiency (EQE) of the light-emitting element is reduced.

According to the light-emitting device 1 of the present embodiment, the thickness dG of the electron transport layer 12G is smaller than the thickness dR of the electron transport layer 12R. As a result, even when the particle size LG of the nanoparticles 12Ga included in the electron transport layer 12G is reduced, the electrical resistance of the electron transport layer 12G as a whole can be reduced. This makes it possible to improve the external quantum efficiency (EQE) of the light-emitting element 3G.

Further, according to the light-emitting device 1 of the present embodiment, the thickness dB of the electron transport layer 12B is smaller than the thickness dG of the electron transport layer 12G. As a result, even when the particle size LB of the nanoparticles 12Ba included in the electron transport layer 12B is reduced, the electrical resistance of the electron transport layer 12B as a whole can be reduced. This makes it possible to improve the external quantum efficiency (EQE) of the light-emitting element 3B.

In this way, according to the light-emitting device 1, the particle size LG of the nanoparticles Ga included in the electron transport layer 12G is smaller particle size LR of the nanoparticles Ra included in the electron transport layer 12R, and the thickness dG of the electron transport layer 12G is smaller than the thickness dR of the electron transport layer 12R. Further, according to the light-emitting device 1, the particle size LB of the nanoparticles Ba included in the electron transport layer 12B is smaller than the particle size LG of the nanoparticles Ga included in the electron transport layer 12G, and the thickness dB of the electron transport layer 12B is smaller than the thickness dG of the electron transport layer 12G. This makes it possible to improve the external quantum efficiency (EQE) of the light-emitting device 1, as compared to the organic electroluminescence image display device of PTL 1.

Note that it is required that in the light-emitting device 1, at least, the particle size LG of the nanoparticles Ga included in the electron transport layer 12G is smaller than the particle size LR of the nanoparticles Ra included in the electron transport layer 12R, and the thickness dG of the electron transport layer 12G is smaller than the thickness dR of the electron transport layer 12R. Alternatively, in the light-emitting device 1, at least, the particle size LB of the nanoparticles Ba included in the electron transport layer 12B may be smaller than the particle size LR of the nanoparticles Ra included in the electron transport layer 12R, and the thickness dB of the electron transport layer 12B may be smaller than the thickness dR of the electron transport layer 12R. Alternatively, in the light-emitting device 1, at least, the particle size LB of the nanoparticles Ba included in the electron transport layer 12B may be smaller than the particle size LG of the nanoparticles Ga included in the electron transport layer 12G, and the thickness dB of the electron transport layer 12B may be smaller than the thickness dG of the electron transport layer 12G. This also makes it possible to improve the external quantum efficiency (EQE) of the light-emitting device 1.

In addition, in the above, description has been given, as an example, assuming that the nanoparticles 12Ra, 12Ga, 12Ba of the electron transport layers 12R, 12G, 12B include a material of the same composition system (ZnO as an example). By using a material of the same composition system for the nanoparticles 12Ra, 12Ga, 12Ba in this manner, it is possible to simplify manufacturing processes of the electron transport layers 12R, 12G, 12B, as compared to a case where materials of different composition systems are used for the nanoparticles.

Here, in the light-emitting device 1, the nanoparticles 12Ra, 12Ga, 12Ba are required to include Zn_{1-X}Mg_{X}O (where 0≤X<1 is satisfied) which is a material of a composition system. Any two of the nanoparticles 12Ra, 12Ga, 12Ba may contain a material of the same composition, and the remaining one may contain a material of a different composition system. For example, the nanoparticles 12Ra may include ZnO (X=0 in Zn_{1-X}Mg_{X}O), and the nanoparticles 12Ga, 12Ba may each include Zn_{1-X}Mg_{X}O (X=0.1).

At least one of the nanoparticles 12Ra, 12Ga, 12Ba preferably contains Mg-added ZnO, that is, a structure in which some Zn in ZnO is replaced with Mg (that is, 0<X<1 in Zn_{1-X}Mg_{X}O). In this manner, increasing a proportion of replacement of Zn with Mg makes it easy to adjust to reduce the ionization potential and the electron affinity of each of the electron transport layers 12R, 12G, 12B. Thus, by adjusting the proportion of replacement of Zn with Mg, it is possible to adjust so that the electron affinities of the electron transport layers 12R, 12G, 12B are brought closer to the electron affinities of the light-emitting layers 13R, 13G, 13B, respectively. This makes it possible to improve the transport efficiency of electrons from the electron transport layers 12R, 12G, 12B to the light-emitting layers 13R, 13G, 13B.

Among the nanoparticles 12Ra, 12Ga, 12Ba, the nanoparticles 12Ga preferably have a larger composition ratio X of Mg in Zn_{1-X}Mg_{X}O (where 0≤X<1 is satisfied) than that of the nanoparticles 12Ra. This makes it possible to make the electron affinity of the electron transport layer 12G smaller than the electron affinity of the electron transport layer 12R. That is, the arranged order in which the electron affinities of the electron transport layer 12R and the electron transport layer 12G decrease can be adjusted to the arranged order in which the electron affinity is reduced in the order of the light-emitting layer 13R and the light-emitting layer 13G. In other words, the electron affinity of the electron transport layer 12R can be brought closer to the intermediate value between the electron affinity of the light-emitting layer 13R and the Fermi level of the cathode 11R. In addition, the electron affinity of the electron transport layer 12G can be brought closer to the intermediate value between the electron affinity of the light-emitting layer 13G and the Fermi level of the cathode 11G. As a result, it is possible to improve the efficiency of transporting electrons from the cathode 11R to the light-emitting layer 13R via the electron transport layer 12R. In addition, it is possible to improve the efficiency of transporting electrons from the cathode 11G to the light-emitting layer 13G via the electron transport layer 12G.

Further, among the nanoparticles 12Ra, 12Ga, 12Ba, the nanoparticles 12Ba preferably have a larger composition ratio X of Mg in Zn_{1-X}Mg_{X}O (where 0≤X<1 is satisfied) than that of the nanoparticles 12Ga. This makes it possible to make the electron affinity of the electron transport layer 12B smaller than the electron affinity of the electron transport layer 12G. That is, the arranged order in which the electron affinities of the electron transport layer 12G and the electron transport layer 12B decrease can be adjusted to the arranged order in which the electron affinity is reduced in the order of the light-emitting layer 13G and the light-emitting layer 13B. In other words, the electron affinity of the electron transport layer 12G can be brought closer to the intermediate value between the electron affinity of the light-emitting layer 13G and the Fermi level of the cathode 11G. In addition, the electron affinity of the electron transport layer 12B can be brought closer to the intermediate value between the electron affinity of the light-emitting layer 13B and the Fermi level of the cathode 11B. As a result, it is possible to improve the efficiency of transporting electrons from the cathode 11G to the light-emitting layer 13G via the electron transport layer 12G. In addition, it is possible to improve the efficiency of transporting electrons from the cathode 11B to the light-emitting layer 13B via the electron transport layer 12B.

Note that it is required that among the nanoparticles 12Ra, 12Ga, 12Ba, the nanoparticles 12Ba have a larger composition ratio X of Mg in Zn_{1-X}Mg_{X}O (where 0≤X<1 is satisfied) than that of at least one of the nanoparticles 12Ra and the nanoparticles 12Ga. Alternatively, it is required that the nanoparticles 12Ra have a smaller composition ratio X of Mg in Zn_{1-X}Mg_{X}O (where 0≤X<1 is satisfied) than that of at least one of the nanoparticles 12Ga and the nanoparticles 12Ba.

Further, the composition ratio X of Zn_{1-X}Mg_{X}O contained in each of the nanoparticles 12Ra, 12Ga, 12Ba preferably satisfies 0.5 nanoparticles 12Ra<nanoparticles 12Ga<nanoparticles 12Ba≤0.5. This makes it possible to bring the electron affinity of the electron transport layer 12R closer to the intermediate value between the electron affinity of the light-emitting layer 13R and the Fermi level of the cathode 11R. Further, it is possible to bring the electron affinity of the electron transport layer 12G closer to the intermediate value between the electron affinity of the light-emitting layer 13G and the Fermi level of the cathode 11G. Further, it is possible to bring the electron affinity of the electron transport layer 12B closer to the intermediate value between the electron affinity of the light-emitting layer 13B and the Fermi level of the cathode 11B.

As an example, a difference between the electron affinity of the electron transport layer 12R and the electron affinity of the light-emitting layer 13R (barrier of electron transportability) is preferably 0.5 eV or less. Further, a difference between the electron affinity of the electron transport layer 12G and the electron affinity of the light-emitting layer 13G (barrier of electron transportability) is preferably 0.5 eV or less. Further, a difference between the electron affinity of the electron transport layer 12B and the electron affinity of the light-emitting layer 13B (barrier of electron transportability) is preferably 0.5 eV or less.

This makes it easy to bring the electron affinity of the electron transport layer 12R closer to the intermediate value between the electron affinity of the light-emitting layer 13R and the Fermi level of the cathode 11R. Further, it becomes easy to bring the electron affinity of the electron transport layer 12G closer to the intermediate value between the electron affinity of the light-emitting layer 13G and the Fermi level of the cathode 11G. Further, it becomes easy to bring the electron affinity of the electron transport layer 12B closer to the intermediate value between the electron affinity of the light-emitting layer 13B and the Fermi level of the cathode 11B.

In addition, it is required that in the light-emitting device 1, among the particle sizes LR, LG, LB of the nanoparticles 12Ra, 12Ga, 12Ba, the particle size LB is smaller than at least one of the particle size LR and the particle size LG. Alternatively, it is required that in the light-emitting device 1, among the particle sizes LR, LG, LB of the nanoparticles 12Ra, 12Ga, 12Ba, the particle size LR is larger than at least one of the particle size LG and the particle size LB.

For example, the particle size LR and the particle size LG may be the same, and the particle size LB may be smaller than the particle size LR and the particle size LG. As an example, the particle size LR of the nanoparticles 12Ra may be 6 nm, the particle size LG of the nanoparticles 12Ga may be 6 nm, and the particle size LB of the nanoparticles 12Ba may be 3 nm.

Further, it is required that in the light-emitting device 1, among the thicknesses dR, dG, dB of the electron transport layers 12R, 12G, 12G, the thickness dB is smaller than at least one of the thickness dR and the thickness dG. Alternatively, it is required that in the light-emitting device 1, among the thicknesses dR, dG, dB of the electron transport layers 12R, 12G, 12G, the thickness dR is larger than at least one of the thickness dG and the thickness dB.

For example, the thickness dR and the thickness dG may be the same, and the thickness dB may be smaller than the thickness dR and the thickness dG. As an example, the thickness dR of the electron transport layer 12R may be 60 nm, the thickness dG of the electron transport layer 12G may be 60 nm, and the thickness dB of the electron transport layer 12B may be 30 nm.

Further, as illustrated in FIG. 4, preferably, the electron affinity of the electron transport layer 12R is the electron affinity or less of the light-emitting layer 13R and is the Fermi level or less of the cathode 11R. As a result, as compared to a case where the electron affinity of the electron transport layer is less than the electron affinity of the light-emitting layer or the electron affinity of the electron transport layer is greater than the Fermi level of the cathode, it is possible to reduce the barrier in transporting electrons injected from the cathode 11R into the electron transport layer 12R to the light-emitting layer 13R. This makes it possible to efficiently transport electrons injected from the cathode 11R into the electron transport layer 12R to the light-emitting layer 13R.

Further, as illustrated in FIG. 5, preferably, the electron affinity of the electron transport layer 12G is the electron affinity or greater of the light-emitting layer 13G and is the Fermi level or less of the cathode 11G. As a result, as compared to a case where the electron affinity of the electron transport layer is less than the electron affinity of the light-emitting layer or the electron affinity of the electron transport layer is greater than the Fermi level of the cathode, it is possible to reduce the barrier in transporting electrons injected from the cathode 11G into the electron transport layer 12G to the light-emitting layer 13G. This makes it possible to efficiently transport electrons injected from the cathode 11G into the electron transport layer 12G to the light-emitting layer 13G.

Further, as illustrated in FIG. 6, preferably, the electron affinity of the electron transport layer 12B is the electron affinity or greater of the light-emitting layer 13B and is the Fermi level or less of the cathode 11B. As a result, as compared to a case where the electron affinity of the electron transport layer is less than the electron affinity of the light-emitting layer or the electron affinity of the electron transport layer is greater than the Fermi level of the cathode, it is possible to reduce the barrier in transporting electrons injected from the cathode 11B into the electron transport layer 12B to the light-emitting layer 13B. This makes it possible to efficiently transport electrons injected from the cathode 11B into the electron transport layer 12B to the light-emitting layer 13B.

In addition, as illustrated in FIGS. 4 to 6, the electron affinity of the electron transport layer 12R is preferably intermediate between the electron affinity of the light-emitting layer 13R and the Fermi level of the cathode 11R. Further, the electron affinity of the electron transport layer 12G is preferably intermediate between the electron affinity of the light-emitting layer 13G and the Fermi level of the cathode 11G. Further, the electron affinity of the electron transport layer 12B is preferably intermediate between the electron affinity of the light-emitting layer 13B and the Fermi level of the cathode 11B.

With this configuration, as compared to a case where the electron affinity of the electron transport layer is not intermediate between the electron affinity of the light-emitting layer and the Fermi level of the cathode, it is possible to reduce the barrier in injecting electrons from the cathodes 11R, 11G, 11B into the electron transport layers 12R, 12G, 12B and transporting the electrons from the electron transport layers 12R, 12G, 12B to the light-emitting layers 13R, 13G, 13B. As a result, it is possible to improve the external quantum efficiency (EQE) of the light-emitting device 1.

Note that when the electron affinity of each of the electron transport layers 12R, 12G, 12B is “intermediate” between the electron affinity of each of the light-emitting layers 13R, 13G, 13B and the Fermi level of each of the cathodes 11R, 11G, 11B, the tolerance is within ±0.2 eV.

In the example illustrated in FIG. 4, the electron affinity of the electron transport layer 12R is 3.9 eV, which is intermediate between the electron affinity of 3.4 eV of the light-emitting layer 13R and the Fermi level of 4.3 eV of the anode 15. Further, in the example illustrated in FIG. 5, the electron affinity of the electron transport layer 12G is 3.7 eV, which is intermediate between the electron affinity of 3.1 eV of the light-emitting layer 13G and the Fermi level of 4.3 eV of the anode 15. Further, in the example illustrated in FIG. 6, the electron affinity of the electron transport layer 12B is 3.5 eV, which is intermediate between the electron affinity of 2.7 eV of the light-emitting layer 13B and the Fermi level of 4.3 eV of the anode 15.

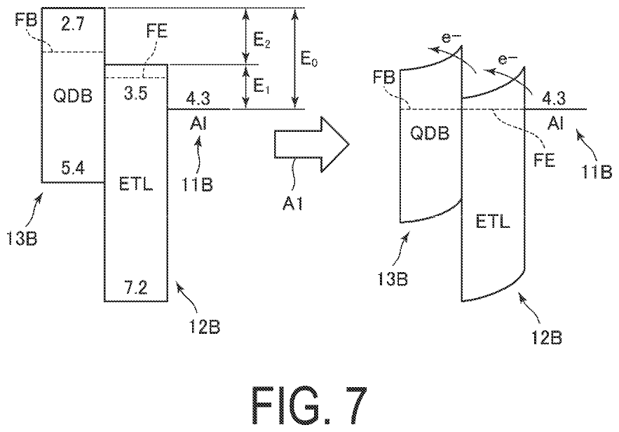

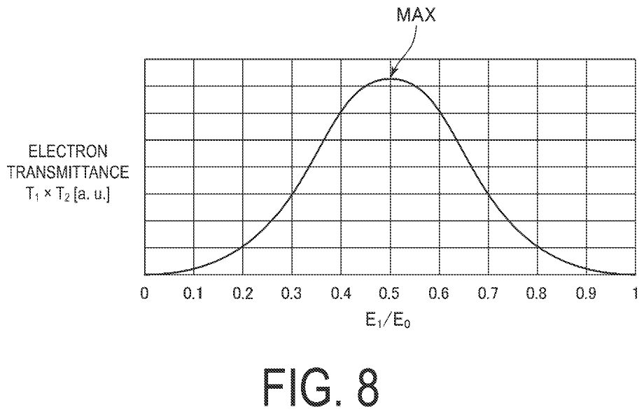

Next, with reference to FIGS. 7 and 8, for a reason why it is preferable that the electron affinity of each of the electron transport layers 12R, 12G, 12B be “intermediate” between the electron affinity of each of the light-emitting layers 13R, 13G, 13B and the Fermi level of each of the cathodes 11R, 11G, 11B, one supposed consideration will be given below. The case of the light-emitting element 3B will be described as an example, but the same can be seen in the case of each of the light-emitting elements 3R, 13G, and thus the description thereof will be omitted.

FIG. 7 illustrates states before and after the upper ends of the valence band levels and the lower ends of the conductor levels of the light-emitting layer 13B and the electron transport layer 12B are bent in the light-emitting element 3B of the light-emitting device 1 according to the embodiment. In FIG. 7, the energy diagram on the left side illustrates a state of the ionization potential and the electron affinity in a case where each of the light-emitting layer 13B and the electron transport layer 12B is a single layer without taking into account joint of the light-emitting layer 13B and the electron transport layer 12B, and the energy diagram on the right side illustrates a state of the ionization potential and the electron affinity taking into account thermal equilibrium in a case where the light-emitting layer 13B and the electron transport layer 12B are joined.

As in the energy diagram on the left side in FIG. 7, in a case where the thermal equilibrium of each layer is not taken into account, when the Fermi level (4.3 eV) of the cathode 11B, the electron affinity (3.5 eV) of the electron transport layer 12B, and the electron affinity (2.7 eV) of the light-emitting layer 13B before the cathode 11B, the electron transport layer 12B, and the light-emitting layer 13B are layered and voltage is applied to the light-emitting element 3B are compared, the values are reduced in stages. Thus, a Fermi level FE larger than the Fermi level of the cathode 11B and the electron affinity (3.5 eV) in the electron transport layer 12B, and a Fermi level FB larger than the electron affinity (2.7 eV) in the light-emitting layer 13B are reduced in stages.

Then, as illustrated by an arrow Al in FIG. 7, when the thermal equilibrium of each layer in the light-emitting element 3B is taken into account, as in the energy diagram on the right side in FIG. 7, the lower end of the conductor level and the upper end of the valence band level of the electron transport layer 12B and the lower end of the conductor level and the upper end of the valence band level of the light-emitting layer 13B are bent in such a manner that the Fermi level FE of the electron transport layer 12B and the Fermi level FB of the light-emitting layer 13B coincide with the Fermi level of the cathode 11B.

Specifically, for example, the lower end of the conductor level of the electron transport layer 12B decreases while being brought closer to the cathode JIB from the light-emitting layer 13B. In the energy diagram illustrated on the right side in FIG. 7, the lower end of the conductor level of the electron transport layer 12B is bent so as to be reduced exponentially (to increase a reduction amount) while being brought closer to the cathode 11B from the light-emitting layer 13B.

Further, specifically, for example, the lower end of the conductor level of the light-emitting layer 13B is reduced while being brought closer to the electron transport layer 12B from the hole transport layer 14R. In the energy diagram illustrated on the right side in FIG. 7, the lower end of the conductor level of the light-emitting layer 13B is bent so as to be reduced exponentially (to increase a decrease amount) while being brought closer to the electron transport layer 12B from the hole transport layer 14R (not illustrated in FIG. 7).

As described above, when the lower end of the conductor level of the electron transport layer 12B and the lower end of the conductor level of the light-emitting layer 13B are bent, electrons e⁻ injected from the cathode 11B into the electron transport layer 12B tunnel through a barrier portion of the barrier when electrons e⁻ are injected from the cathode 11B into the electron transport layer 12B, the barrier portion having a reduced thickness. This reduces the barrier when electrons e⁻ are injected from the cathode 11B into the electron transport layer 12B, as compared to before the lower end of the conductor level of the electron transport layer 12B and the lower end of the conductor level of the light-emitting layer 13B are bent.

Further, electrons e⁻ transported from the electron transport layer 12B to the light-emitting layer 13R tunnel through a barrier portion of the barrier when electrons e⁻ are transported from the electron transport layer 12B to the light-emitting layer 13B, the barrier portion having a reduced thickness. This reduces the barrier when electrons e⁻ are transported from the electron transport layer 12B to the light-emitting layer 13B, as compared to before the electron affinity of the electron transport layer 12B and the electron affinity of the light-emitting layer 13B are bent.

As illustrated in the energy diagram on the left side in FIG. 7, when a difference between the Fermi level of the cathode 11B and the lower end of the conductor level of the light-emitting layer 13B is defined as E₀, a difference between the Fermi level of the cathode 11B and the lower end of the conductor level of the electron transport layer 12B is defined as E₁, and a difference between the electron affinity of the electron transport layer 12B and the electron affinity of the light-emitting layer 13B is defined as E₂, E₀, E₁, and E₂ can be expressed by the following (Equation 1).

E₁+E₂=E₀ (constant) (Equation 1)

In addition, according to a Fowler-Nordheim model, an amount of electrons e⁻ injected from the cathode 11B into the electron transport layer 12B can be quantified using a tunnel transmittance T₁ and can be expressed by the following (Equation 2). Here, m is an electron efficiency amount, e is an elementary charge, h is a Planck constant, and F is an electrolysis (the same applies to the subsequent equations).

$$\begin{matrix}[ Expression 1 ] & \\ {T}_{1} = exp [ - \frac{8 {π ( 2 m )}^{1 / 2} {E}_{1}^{3 / 2}}{3 ehF} ] & ( Equation 2 )\end{matrix}$$

Further, according to the Fowler-Nordheim model, electrons e⁻ transported from the electron transport layer 12B to the light-emitting layer 13B can be quantified using a tunnel transmittance T₂ and can be expressed by the following (Equation 3).

$$\begin{matrix}[ Expression 2 ] & \\ {T}_{2} = exp [ - \frac{8 {π ( 2 m )}^{1 / 2} {E}_{2}^{3 / 2}}{3 ehF} ] & ( Equation 3 )\end{matrix}$$

In addition, T₁×T₂ is referred to as an electron transmittance when electrons are injected from the cathode 11B into the light-emitting layer 13B. The electron transmittance T₁×T₂ is an index that indicates the efficiency when electrons are injected from the cathode 11B to the light-emitting layer 13B. The electron transmittance T₁×T₂ can be expressed by the following (Equation 4).

$$\begin{matrix}[ Expression 3 ] & \\ {T}_{1} \times {T}_{2} = exp [ - \frac{8 {π ( 2 m )}^{1 / 2} \{ {E}_{1}^{3 / 2} + {( {E}_{0} - {E}_{1} )}^{3 / 2} \}}{3 ehF} ] & ( Equation 4 )\end{matrix}$$

FIG. 8 is a diagram showing a graph of an electron transmittance T₁×T₂ of the light-emitting device 1 according to the embodiment. In the graph of FIG. 8, the horizontal axis indicates E₁/E₀, and the vertical axis indicates the electron transmittance T₁×T₂.

As expressed by the above (Equation 1), when E₁+E₂=E₀ is satisfied, as shown in the graph of FIG. 8, the electron transmittance T₁×T₂ becomes the maximum when E₁/E₀=0.5 is satisfied, as indicated by MAX in FIG. 8. That is, it is when E₁=E₂=E₀/2 is satisfied.

According to this examination result, it can be thought that the electron affinity of the electron transport layer 12B is intermediate between the electron affinity of the light-emitting layer 13B and the Fermi level of the cathode 11B, and thus the injection efficiency of electrons injected from the cathode 11B to the light-emitting layer 13B via the electron transport layer 12B is improved.

Note that it is also considerable that the electron affinity of the electron transport layer 12R is intermediate between the electron affinity of the light-emitting layer 13R and the Fermi level of the cathode 11R, and thus the injection efficiency of electrons injected from the cathode 11R into the light-emitting layer 13R via the electron transport layer 12R is improved. Further, it is also considerable that the electron affinity of the electron transport layer 12G is intermediate between the electron affinity of the light-emitting layer 13G and the Fermi level of the cathode 11G, and thus the injection efficiency of electrons injected from the cathode 11G into the light-emitting layer 13G via the electron transport layer 12G is improved.

Note that the electron affinity of the light-emitting layer 13G is smaller than the electron affinity of the light-emitting layer 13R, and the electron affinity of the light-emitting layer 13B is smaller than the electron affinity of the light-emitting layer 13G. Thus, preferably, the electron affinity of the electron transport layer 12B is the electron affinity or less of the electron transport layer 12G, and the electron affinity of the electron transport layer 12G is the electron affinity or less of the electron transport layer 12R. As a result, it is possible to efficiently inject electrons from the cathodes 11R, 11G, 11B into the light-emitting layers 13R, 13G, 13B via the electron transport layers 12R, 12G, 12B, respectively.

Note that it is required that in the light-emitting device 1, among the electron transport layer 12R, the electron transport layer 12G, and the electron transport layer 12B, the electron affinity of at least the electron transport layer 12B is the electron affinity or less of at least one of the electron transport layer 12R and the electron transport layer 12G. Alternatively, it is required that in the light-emitting device 1, among the electron transport layer 12R, the electron transport layer 12G, and the electron transport layer 12B, the electron affinity of at least the electron transport layer 12R is the electron affinity or greater of at least one of the electron transport layer 12G and the electron transport layer 12B.

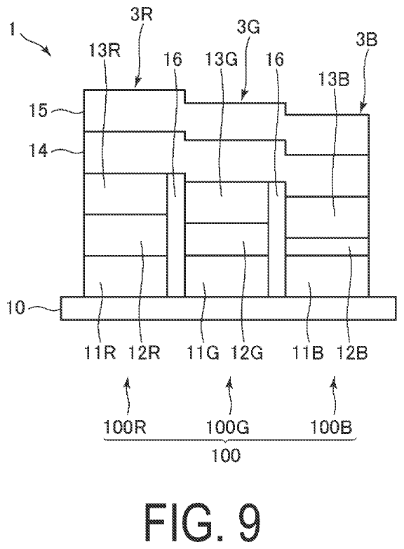

Further, the light-emitting elements 3R, 3G, 3B in the light-emitting device 1 can employ various other structures without being limited to the structure illustrated in FIG. 1. Several examples in which the structure of the light-emitting elements 3R, 3G, 3B in the light-emitting device 1 illustrated in FIG. 1 is modified will be described with reference to FIGS. 9 to 11.

FIG. 9 is a cross-sectional view schematically illustrating a layered structure of the light-emitting device 1 according to a first modified example of the embodiment. The light-emitting elements 3R, 3G, 3B of the light-emitting device 1 illustrated in FIG. 9 include a hole transport layer 14 instead of the hole transport layers 14R, 14G, 14B separated into an island shape in the light-emitting elements 3R, 3G, 3B of the light-emitting device 1 illustrated in FIG. 1.

The hole transport layer 14 is a layer continuous over the light-emitting elements 3R, 3G, 3B. The hole transport layer 14 covers the light-emitting layers 13R, 13G, 13B, and the banks 16. The hole transport layer 14 is provided on a side opposite to the electron transport layers 12R, 12G, 12B with respect to the light-emitting layers 13R, 13G, 13B. That is, the hole transport layer 14 is provided between the light-emitting layers 13R, 13G, 13B and the anode 15. The hole transport layer 14 can be formed using a material similar to that of the hole transport layers 14R, 14G, 14B.

However, the hole transport layer 14 is different from the hole transport layers 14R, 14G, 14B, does not need to be patterned for each of the light-emitting elements 3R, 3G, 3B, and is formed over the entire surface of the display region in the light-emitting device 1, so-called in a solid manner (so as to be continuous over the light-emitting elements 3R, 3G, 3B). Thus, for example, even when the hole transport layer 14 is formed by the ink-jet method, separate application is not necessary to each of the light-emitting elements 3R, 3G, 3B. Alternatively, for example, even when the hole transport layer 14 is formed using vapor deposition or photolithography, a high-definition mask or the like necessary when patterning is performed for each of the light-emitting elements 3R, 3G, 3B is not required.

In this manner, according to the light-emitting device 1 illustrated in FIG. 9, the structure and manufacturing method of the hole transport layer 14 can be simplified.

Further, the ionization potentials of the light-emitting layers 13R, 13G, 13B are constant regardless of a color of emitted light, and thus even when the hole transport layer 14 is formed continuously over the light-emitting layers 13R, 13G, 13B, it is possible to improve the injection efficiency of positive holes from the anode 15 into the light-emitting layers 13R, 13G, 13B via the hole transport layer 14.

That is, according to the light-emitting device 1 in FIG. 9, it is possible to improve the injection efficiency of positive holes into the light-emitting layers 13R, 13G, 13B and to further simplify the structure and manufacturing method of the hole transport layer 14.

Note that the hole transport layer 14 does not need to be a layer continuous over all the light-emitting elements 3R, 3G, 3B and may be a layer continuous over any two of the light-emitting elements 3R, 3G, 3B.

FIG. 10 is a cross-sectional view schematically illustrating a layered structure of the light-emitting device 1 of a second modified example of the embodiment. The light-emitting elements 3R, 3G, 3B of the light-emitting device 1 illustrated in FIG. 10 include a cathode 11 instead of the cathodes 11R, 11G, 11B separated into an island shape in the light-emitting elements 3R, 3G, 3B of the light-emitting device 1 illustrated in FIG. 9.

The cathode 11 is a layer continuous over the light-emitting elements 3R, 3G, 3B. In other words, the cathode 11 can be expressed as a layer including the cathode 11R provided for each light-emitting element 3R (a partial region of the cathode 11), the cathode 11G provided for each light-emitting element 3G (a partial region of the cathode 11), and the cathode 11B provided for each light-emitting element 3B (a partial region of the cathode 11), in which the cathode 11R, the cathode 11G, and the cathode 11B are continuous without being separated. The cathode 11 is provided on a side opposite to the light-emitting layers 13R, 13G, 13B with respect to the electron transport layers 12R, 12G, 12B. That is, the cathode 11 is provided between the electron transport layers 12R, 11G, 11B and the array substrate 10.

The cathode 11 can be formed using a material similar to that of the cathodes 11R, 11G, 11B described with reference to FIG. 1. However, the cathode 11 is different from the cathodes 11R, 11G, 11B described with reference to FIG. 1, does not need to be patterned for each of the light-emitting elements 3R, 3G, 3B, and is formed over the entire surface of the display region in the light-emitting device 1, so-called in a solid manner. Thus, when the cathode 11 is formed by, for example, the sputtering or vapor deposition method, a high-definition mask or the like necessary when patterning is performed for each of the light-emitting elements 3R, 3G, 3B is not required.

In this manner, according to the light-emitting device 1 illustrated in FIG. 10, it is possible to simplify the structure and manufacturing method of the cathode 11. That is, according to the light-emitting device 1 illustrated in FIG. 10, it is possible to efficiently inject electrons from the cathode 11 to the light-emitting layers 13R, 13G, 13B via the electron transport layers 12R, 12G, 12B, and to simplify the structure and manufacturing method of the cathode 11.

According to the light-emitting device 1 illustrated in FIG. 10, both the cathode 11 and the anode 15 are common layers continuous over the light-emitting elements 3R, 3G, 3B. Thus, in the light-emitting device 1 illustrated in FIG. 10, light emission and non-light emission of the light-emitting elements 3R, 3G, 3B are not individually controlled, but light emission and non-light emission of the light-emitting elements 3R, 3G, 3B are simultaneously controlled. That is, the light-emitting elements 3R, 3G, 3B of the light-emitting device 1 illustrated in FIG. 10 are a light-emitting element that emits white light in which red light, green light, and blue light are mixed. This allows the light-emitting device 1 illustrated in FIG. 10 to be suitably used for various illumination devices, such as a backlight device in a liquid crystal display device or the like, or an illumination device that illuminates various spaces.

Note that when the light-emitting device 1 illustrated in FIG. 10 is used as an illumination device, in the light-emitting elements 3R, 3G, 3B, the cathode 11 does not necessarily need to be connected to a TFT provided in the array substrate 10 for each of the light-emitting elements 3R, 3G, 3B. The cathode 11 may be connected to a TFT provided in the array substrate 10 for a predetermined plurality of light-emitting elements to control light emission and non-light emission of the light-emitting elements 3R, 3G, 3B as an integrated body for the predetermined plurality of light-emitting elements.

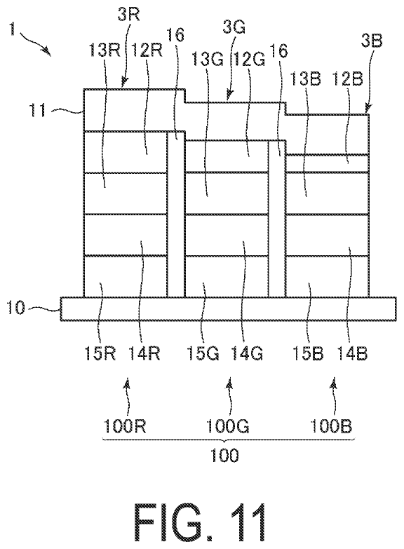

FIG. 11 is a cross-sectional view schematically illustrating a layered structure of the light-emitting device 1 of a third modified example of the embodiment. The light-emitting elements 3R, 3G, 3B of the light-emitting device 1 illustrated in FIG. 11 have a configuration in which the layered order of layers in the light-emitting elements 3R, 3G, 3B of the light-emitting device 1 illustrated in FIG. 1 is inverted.

The light-emitting element 3R of the light-emitting device 1 illustrated in FIG. 11 includes an anode (first anode) 15R layered on the array substrate 10, the hole transport layer 14R layered on the anode 15R, the light-emitting layer 13R layered on the hole transport layer 14R, and the electron transport layer 12R layered on the light-emitting layer 13R. For example, the anode 15R, the hole transport layer 14R, the light-emitting layer 13R, and the electron transport layer 12R are provided in an island shape separated for each light-emitting element 3R (in other words, each subpixel 100R). Further, the light-emitting element 3G includes an anode (second anode) 15G layered on the array substrate 10, the hole transport layer 14G layered on the anode 15G, the light-emitting layer 13G layered on the hole transport layer 14G, and the electron transport layer 12G layered on the light-emitting layer 13G. For example, the anode 15G, the hole transport layer 14G, the light-emitting layer 13G, and the electron transport layer 12G are provided in an island shape separated for each light-emitting element 3G (in other words, each subpixel 100G). Further, the light-emitting element 3B includes an anode (third anode) 15B layered on the array substrate 10, the hole transport layer 14B layered on the anode 15B, the light-emitting layer 13B layered on the hole transport layer 14B, and the electron transport layer 12B layered on the light-emitting layer 13B. For example, the anode 15B, the hole transport layer 14B, the light-emitting layer 13B, and the electron transport layer 12B are provided in an island shape separated for each light-emitting element 3B (in other words, subpixel 100B).

In addition, the light-emitting elements 3R, 3G, 3B has the cathode 11, which is a layer continuous over the elements. In other words, the cathode 11 is a common electrode common to the light-emitting elements 3R, 3G, 3B without being separated for each of the light-emitting elements 3R, 3G, 3B. The cathode 11 is layered on the electron transport layers 12R, 12G, 12B and the banks 16.

For materials of layers of the light-emitting elements 3R, 3G, 3B of the light-emitting device 1 illustrated in FIG. 11, materials similar to those of the layers of the light-emitting elements 3R, 3G, 3B of the light-emitting device 1 illustrated in FIG. 1 can be used.

Further, the anodes 15R, 15G, 15B may include a reflective metal layer having a high reflectivity of visible light, and the cathode 11 may include a transparent conductive layer having a high transmittance of visible light. The reflective metal layer having a high reflectivity of visible light can contain metal such as Al, Cu, Au, or Ag, for example. The transparent conductive layer having a high transmittance of visible light can contain a transparent conductive material such as ITO, IZO, ZnO, AZO, or GZO, for example. When the anodes 15R, 15G, 15B among the anodes 15R, 15G, 15B and the cathode 11 are formed as electrodes including metal in this way, oxidation of the electrodes caused by oxidation of the metal can be suppressed, as compared to a case where the cathode is formed as an electrode including metal. This can suppress deterioration with time of the electrodes.

Note that in this case, the light-emitting device 1 is of a top-emitting type in which light emitted by the light-emitting layers 13R, 13G, 13B is caused to pass through the electron transport layers 12R, 12G, 12B and the cathode 11 to be taken out to a side opposite to the array substrate 10 (side above the light-emitting layers 13R, 13G, 13B in FIG. 11).

Note that an aspect of the present invention is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting device comprising:
a first light-emitting element including a first light-emitting layer configured to emit light having a light-emitting central wavelength of a first wavelength, and a first electron transport layer layered with the first light-emitting layer; and
a second light-emitting element including a second light-emitting layer configured to emit light having a light-emitting central wavelength of a second wavelength shorter than the first wavelength, and the second electron transport layer layered with the second light-emitting layer,
wherein each of the first electron transport layer and the second electron transport layer includes a plurality of nanoparticles, and
the second electron transport layer includes the plurality of nanoparticles having a smaller average particle size than the plurality of nanoparticles included in the first electron transport layer, and has a smaller thickness than the first electron transport layer.

2. The light-emitting device according to claim 1,
wherein the plurality of nanoparticles include Zn_{1-X}Mg_{X}O, where X satisfies 0≤X<1.

3. The light-emitting device according to claim 1,
wherein the plurality of nanoparticles have an identical composition.

4. The light-emitting device according to claim 1,
wherein the first light-emitting layer and the second light-emitting layer are adjacent to each other in a plan view, and
the first electron transport layer and the second electron transport layer are adjacent to each other in a plan view.

5. The light-emitting device according to claim 1,
wherein the first light-emitting element includes a first cathode provided on a side opposite to the first light-emitting layer with respect to the first electron transport layer,
the second light-emitting element includes a second cathode provided on a side opposite to the second light-emitting layer with respect to the second electron transport layer,
a conduction band level of the first electron transport layer is a conduction band level or greater of the first light-emitting layer and a Fermi level or less of the first cathode, and
a conduction band level of the second electron transport layer is a conduction band level or greater of the second light-emitting layer and a Fermi level or less of the second cathode.

6. The light-emitting device according to claim 5,
wherein the conduction band level of the first electron transport layer is intermediate between the conduction band level of the first light-emitting layer and the Fermi level of the first cathode.

7. The light-emitting device according to claim 5,
wherein the conduction band level of the second electron transport layer is intermediate between the conduction band level of the second light-emitting layer and the Fermi level of the second cathode.

8. The light-emitting device according to claim 1,
wherein the plurality of nanoparticles included in the second electron transport layer have a larger composition ratio X of Mg than the plurality of nanoparticles included in the first electron transport layer.

9. The light-emitting device according to claim 1, further comprising:
a third light-emitting element including a third light-emitting layer configured to emit light having a light-emitting central wavelength of a third wavelength shorter than the second wavelength, and a third electron transport layer layered with the third light-emitting layer,
wherein the third electron transport layer includes the plurality of nanoparticles having a smaller average particle size than the plurality of nanoparticles included in the second electron transport layer, and has a smaller thickness than the second electron transport layer.

10. The light-emitting device according to claim 9,
wherein light having the light-emitting central wavelength of the first wavelength is red light, light having the light-emitting central wavelength of the second wavelength is green light, and light having the light-emitting central wavelength of the third wavelength is blue light.

11. The light-emitting device according to claim 9,
wherein the second electron transport layer has a smaller conduction band level than the first electron transport layer, and
the third electron transport layer has a smaller conduction band level than the second electron transport layer.

12. The light-emitting device according to claim 9,
wherein the second light-emitting layer has a smaller conduction band level than the first light-emitting layer, and
the third light-emitting layer has a smaller conduction band level than the second light-emitting layer.

13. The light-emitting device according to claim 1,
wherein the first light-emitting element includes a hole transport layer provided on a side opposite to the first electron transport layer with respect to the first light-emitting layer, the second light-emitting element includes a hole transport layer provided on a side opposite to the second electron transport layer with respect to the second light-emitting layer, and
the hole transport layer is a layer continuous over the first light-emitting element and the second light-emitting element.

14. The light-emitting device according to claim 5,
wherein the first light-emitting element has an anode provided on a side opposite to the first electron transport layer with respect to the first light-emitting layer, the second light-emitting element has an anode provided on a side opposite to the second electron transport layer with respect to the second light-emitting layer,
the anode is a layer continuous over the first light-emitting element and the second light-emitting element, and
the first cathode and the second cathode are a layer continuous with each other.

15. The light-emitting device according to claim 5,
wherein the first light-emitting element has a first anode layered on a side opposite to the first electron transport layer with respect to the first light-emitting layer,
the second light-emitting element has a second anode layered on a side opposite to the second electron transport layer with respect to the second light-emitting layer,
the first anode is provided for every first light-emitting element,
the second anode is provided for every second light-emitting element, and
the first cathode and the second cathode are a layer continuous with each other.

16. A method for manufacturing a light-emitting device, the method comprising:
forming a first light-emitting layer configured to emit light having a light-emitting central wavelength of a first wavelength;
forming a second light-emitting layer configured to emit light having a light-emitting central wavelength of a second wavelength shorter than the first wavelength;
forming a first electron transport layer layered with the first light-emitting layer; and
forming a second electron transport layer layered with the second light-emitting layer,
wherein each of the first electron transport layer and the second electron transport layer includes a plurality of nanoparticles, and
the second electron transport layer includes the plurality of nanoparticles having a smaller average particle size than the plurality of nanoparticles included in the first electron transport layer, and has a smaller thickness than the first electron transport layer.
